(19) United States
(12) Patent Application Publication
(10) Pub. No.: US 2010/0159182 A1
(43) Pub. Date: Jun. 24, 2010

(54) Production Method for a Codoped Bulk SiC Crystal and High-Impedance SiC Substrate

(75) Inventors: Thomas Straubinger, Erlangen (DE); Andreas Wohlfart, Erlangen (DE); Martin Kölbl, Nittenau (DE)

Correspondence Address: LERNER GREENBERG STEMER LLP, P O BOX 2480, HOLLYWOOD, FL, 33022-2480, US

(73) Assignee: SICRYSTAL AG, Erlangen (DE)

(21) Appl. No.: 12/647,038

(22) Filed: Dec. 24, 2009

(30) Foreign Application Priority Data
Dec. 24, 2008 (DE) 10 2008 063 129.9

(51) Int. Cl. C30B 23/06; B32B 3/02

(52) U.S. Cl. 428/66.7; 117/84

(57) ABSTRACT

A method is used for producing a bulk SiC crystal having a resistivity of at least 10¹² Ωcm and a diameter of at least 7.62 cm. An SiC growth gas phase is generated in a crystal growth region. The bulk SiC crystal grows by deposition from the SiC growth gas phase. The SiC growth gas phase is fed from an SiC source material, which is contained in an SiC supply region inside the growing crucible. First dopants which have a flat dopant level at a distance of at most 350 meV from an SiC band edge, and second dopants which have a low-lying dopant level at a distance of at least 500 meV from the SiC band edge, are delivered in gaseous form to the crystal growth region. Bulk SiC crystals are thereby obtained, and large-area SiC substrates obtained therefrom whose resistivity is at least 10¹² Ωcm everywhere.

### CROSS-REFERENCE TO RELATED APPLICATION

This application claims the priority, under 35 U.S.C.§119, of German application DE10 2008 063 129.9, filed Dec. 24, 2008; the prior application is herewith incorporated by reference in its entirety.

### BACKGROUND OF THE INVENTION

1. Field of the Invention

The invention relates to a method for producing a bulk SiC crystal and to a monocrystalline SiC substrate.

Owing to its outstanding physical, chemical and electrical properties, the semiconductor material silicon carbide (SiC) is used inter alia as a substrate material for radiofrequency components. In this case, the least possible interaction of the component per se with the substrate material is important in order to avoid losses. This is achieved for example by the monocrystalline SiC substrate having the highest possible electrical resistance besides a high crystalline quality. In order to produce a bulk SiC crystal or an SiC substrate therefrom with high-impedance behavior, it is necessary to compensate for flat defects which exist inside the crystal owing to impurities or intrinsic defects. A high-impedance bulk SiC crystal produced in this way is also referred to as semi-insulating.

In order to compensate for the flat defects, which are caused in particular by nitrogen impurities and preferably act as donors, international patent disclosures WO 02/097173 A2 and WO 2005/012601 A2, corresponding to U.S. Pat. Nos. 6,218,680, 6,396,080, 6,403,982, 6,639,247 and 7,220,313, describe methods in which additional intrinsic defects are deliberately generated during the crystal growth. Resistivity values of from about 10⁵ Ωcm to at most about 10¹⁰ Ωcm can thereby be achieved, although owing to the process management which is very sensitive in this regard, values of only about 10⁶ Ωcm are often achieved. The formation of suitable intrinsic defects depends strongly on the process parameters during the crystal growth, so that even minor process variations lead to an inhomogeneous distribution of defects and therefore resistance. Furthermore, such deliberately introduced intrinsic defects can be annealed out again under a thermal load, which can lead to an inhomogeneous resistance distribution or even entire loss of the high-impedance properties.

International patent disclosure WO 98/34281 A1, corresponding to U.S. Pat. No. 5,611,955, describes another method of compensating for flat defects. Here, deep extrinsic defects are deliberately introduced into the bulk SiC crystal. In order to compensate for the background nitrogen doping (nitrogen impurities), vanadium is used as a deliberately introduced dopant. In this way, resistivity values of 10¹¹ Ωcm can be achieved.

In the doping method described in international patent disclosure WO 2006/017074 A2, corresponding to U.S. patent publication No. 2008/0190355, vanadium is added to the powdered SiC source material from which the growing bulk SiC crystal is fed. For this reason, deliberate and in particular controllable vanadium supply is not possible. Furthermore, the vanadium component in the SiC source material becomes depleted over time, so that it is virtually impossible to set up homogeneous electrical properties in the growing bulk SiC crystal.

International patent disclosure WO 2006/113657 A1, corresponding to U.S. Pat. No. 7,608,524, describes another doping method, in which a vanadium-filled capsule is placed inside the growing crucible with the intention of avoiding depletion of the dopant supply. Yet even with this method, homogeneous electrical properties cannot be set up above all for a bulk SiC crystal with a large diameter of at least 7.62 cm (=3 inches).

By the codoping method described in published, non-prosecuted German patent application DE 43 25 804 A1, corresponding to U.S. Pat. No. 5,856,231, particularly high values can be achieved for the resistivity of the growing bulk SiC crystal and the SiC substrates produced therefrom. In this codoping method, the background nitrogen doping is compensated for by deliberately adding a first dopant with a flat dopant level. Here, a doping level is intended to mean the position of the energy level of a dopant inside the band gap of the relevant semiconductor material. The first dopant is in particular aluminum, which acts as an acceptor. A remaining excess of p-type charge carriers coming from the acceptor dopants is compensated for by the second dopants which are also introduced. The second dopants are vanadium with a low-lying dopant level acting as a donor. Owing to the addition of two different dopants, with this method it is particularly difficult to set up homogeneous electrical properties and in particular a homogeneous resistance distribution.

### SUMMARY OF THE INVENTION

It is accordingly an object of the invention to provide a production method for a codoped bulk SiC crystal and a high-impedance SiC substrate which overcome the above-mentioned disadvantages of the prior art methods and devices of this general type. It is therefore an object of the invention to provide an improved method for producing a bulk SiC crystal, and to provide an improved monocrystalline SiC substrate.

The method according to the invention is one for producing a bulk SiC crystal having a resistivity of at least 10¹² Ωcm and having a diameter of at least 7.62 cm, characterized in that an SiC growth gas phase is generated in a crystal growth region of a growing crucible, and the bulk SiC crystal grows by deposition from the SiC growth gas phase. The SiC growth gas phase is fed from an SiC source material, which is contained in an SiC supply region inside the growing crucible. First dopants which have a flat dopant level at a distance of at most 350 meV from an SiC band edge, and second dopants which have a low-lying dopant level at a distance of at least 500 meV from the SiC band edge, are delivered in gaseous form to the crystal growth region from at least one dopant supply which is arranged outside the growing crucible and the temperature of which can be controlled independently of the SiC source material.

Owing to the inventive placement of the dopant supply outside the growing crucible, and the likewise inventive possibility of controlling the dopant supply temperature, the dopant addition can be adjusted particularly exactly and above all variably as a function of time. Thus, the dopant delivery can be adapted to the current process conditions and above all varied if need be. This flexibility in the dopant delivery is not possible in the previously known methods with direct addition of the dopants to the powdered SiC source material or with placement of a dopant-filled capsule inside the growing crucible. The first dopant may in particular be an acceptor, and the second dopant may in particular be a donor.

In contrast to the known methods, with the method according to the invention a bulk SiC crystal can be produced which has both a very high resistivity, namely at least 10¹² Ωcm, and a very large diameter, namely at least 7.62 cm (at least 3 inches). The method according to the invention thus makes it possible to produce a very large bulk crystal with an extraordinarily high-impedance behavior, which is furthermore preferably provided as homogeneously as possible inside the growing bulk SiC crystal.

According to a particular embodiment, the dopant supply is heated separately from heating of the growing crucible. The temperature of the dopant supply can therefore be deliberately adjusted particularly simply, and above all also varied.

According to another particular embodiment, the dopant supply is arranged in a cavity which is provided inside a thermal insulation layer surrounding the growing crucible. This results in a compact structure of the growing arrangement.

According to another particular embodiment, a position of the dopant supply relative to the growing crucible is varied. The temperature of the dopant supply can also be adjusted by this measure. The dopant supply then lies further or less far inside the region of influence of the heat provided for heating the growing crucible.

According to another particular embodiment, an inert gas flows through the dopant supply. This gives improved transport of the gaseous dopants into the growing crucible. Furthermore, varying the inert gas flow rate thus provides an additional way of regulating/controlling the dopant quantity introduced. In addition, above all with particularly long growing times, the inert gas flow prevents the delivery line to the growing crucible from being constricted by growth of SiC which may enter the colder tube of the delivery line from the hot interior of the growing crucible.

According to another particular embodiment, the first dopants and the second dopants are delivered from a common dopant supply or respectively from separate dopant supplies.

According to another particular embodiment, the first and second dopants are introduced into the SiC supply region or directly into the crystal growth region. When they are introduced into the SiC supply region, the dopants travelled from there into the crystal growth region.

According to another particular embodiment, the first and second dopants are distributed inside the growing crucible, in particular by a gas distributor, by introducing them into the growing crucible in relation to a cross-sectional plane of the growing crucible oriented perpendicularly to a growth direction, in particular at a plurality of adjacent positions. Owing to the distributed delivery of the dopants into the growing crucible, particularly homogeneous conditions can be set up in the SiC growth phase in respect of the dopants contained in it. The growing bulk SiC crystal therefore has a substantially homogeneous electrical behavior, i.e. it has an equally large, in particular high-value resistivity virtually everywhere.

According to another particular embodiment, the first and second dopants are delivered to the crystal growth region so that their respective concentrations within a cross-sectional plane of the growing crucible oriented perpendicularly to a growth direction vary by at most 5% around an average concentration value. A local concentration is determined in particular in relation to an arbitrary 4 mm² large sub-area of the total inner cross-sectional area of the growing crucible. The dopants are thus in particular distributed substantially uniformly within this cross-sectional area.

In order to achieve the object relating to the SiC substrate, a monocrystalline SiC substrate according to the invention contains a main substrate surface, the main substrate surface having a diameter of at least 7.62 cm, and codoping with a first dopant and a second dopant. The first dopant has a flat dopant level that lies at a distance of at most 350 meV from an SiC band edge, and the second dopant having a low-lying dopant level that lies at a distance of at least 500 meV from the SiC band edge. The main substrate surface has a resistivity determined for an arbitrary 4 mm² large sub-area of the main substrate surface being at least 10¹² Ωcm.

The SiC substrate according to the invention thus has on the one hand an extraordinarily large diameter, and on the other hand is distinguished by an extremely high resistivity which is also provided everywhere on the main substrate surface, i.e. on any arbitrary 4 mm² large, in particular square, sub-area. Previous SiC substrates do not have comparable favorable properties. The monocrystalline SiC substrate according to the invention can be used particularly advantageously as a high-impedance or semi-insulating substrate for the production of radiofrequency components. Owing to the large substrate diameter and the high resistivity, which in particular is provided very homogeneously everywhere on the substrate surface, the production of such radiofrequency components is particularly efficient and economical. Such advantageous SiC substrates have not existed to date. They can be produced for the first time from the bulk SiC crystals grown by the method according to the invention as described above.

According to a particular embodiment, the first dopant is an acceptor and overcompensates for impurities acting as donors.

According to another embodiment, the first dopant is aluminum or boron.

According to another particular embodiment, the first dopant is aluminum and has a concentration of between 1·10¹⁶ cm⁻³ and 5·10¹⁷ cm⁻³.

According to another particular embodiment, the second dopant is a donor and at least equalizes any overcompensation by the first dopant in relation to impurities.

According to another particular embodiment, the second dopant is vanadium or scandium.

According to another particular embodiment, the second dopant is vanadium and has a concentration of between 1·10¹⁶ cm⁻³ and 5·10¹⁷ cm⁻³.

According to another particular embodiment, the second dopant has a higher concentration than the first dopant.

According to another particular embodiment, a local concentration of the first and/or second dopant, determined for an arbitrary sub-volume, deviates by less than 5% of an overall concentration of the first and/or second dopant, the sub-volume being defined by an arbitrary 4 mm² large sub-area of the main substrate surface and perpendicularly thereto by a substrate thickness. The overall concentration is determined as a whole, i.e. for the entire SiC substrate. It therefore represents an average concentration value. The high homogeneity is provided in particular both in the lateral (radial) direction, i.e. perpendicularly to the growth direction of the bulk SiC crystal from which the SiC substrate is fabricated, and in the axial direction, i.e. in the growth direction of the bulk SiC crystal. The extremely homogeneous incorporation of the dopants leads to a very homogeneous electrical behavior of the SiC substrate. The resistivity is subject to only very minor variations, if at all, as seen over the main substrate surface. The SiC substrate can consequently be used with high yield as a high-impedance or semi-insulating substrate for the production of radiofrequency components.

Other features which are considered as characteristic for the invention are set forth in the appended claims.

Although the invention is illustrated and described herein as embodied in a production method for a codoped bulk SiC crystal and a high-impedance SiC substrate, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

BRIEF DESCRIPTION OF THE SEVERAL VIEWS OF THE DRAWING

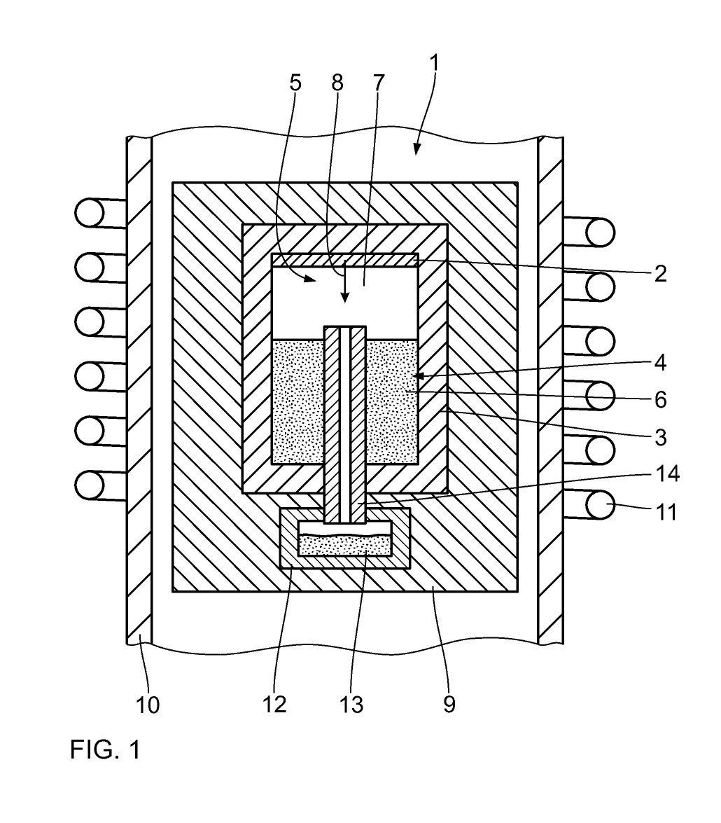

FIG. 1 is a diagrammatic, sectional view of a first exemplary embodiment of a growing arrangement for producing a high-impedance bulk SiC crystal with an external dopant supply according to the invention;

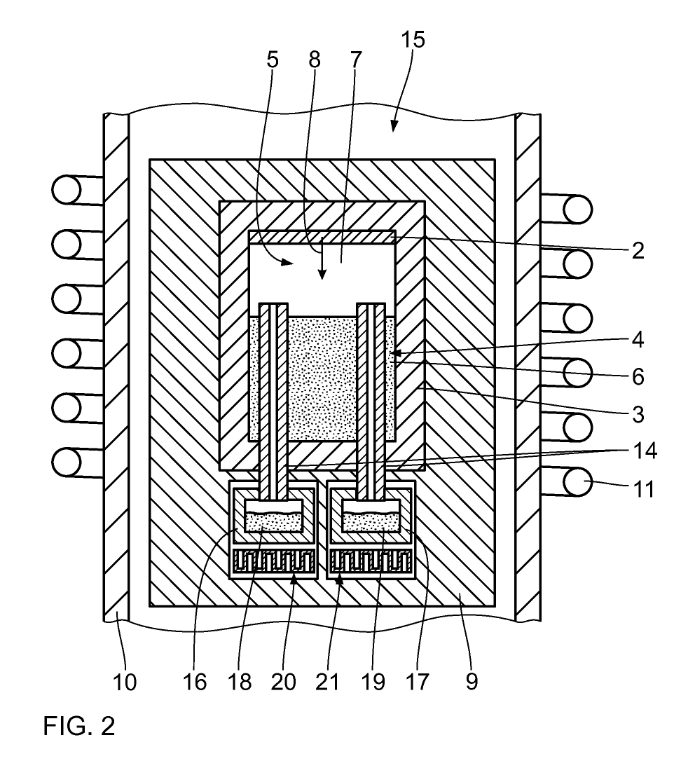

FIG. 2 is a diagrammatic, sectional view of a second exemplary embodiment of a growing arrangement for the production of a high-impedance bulk SiC crystal with two separately heatable external dopant supplies;

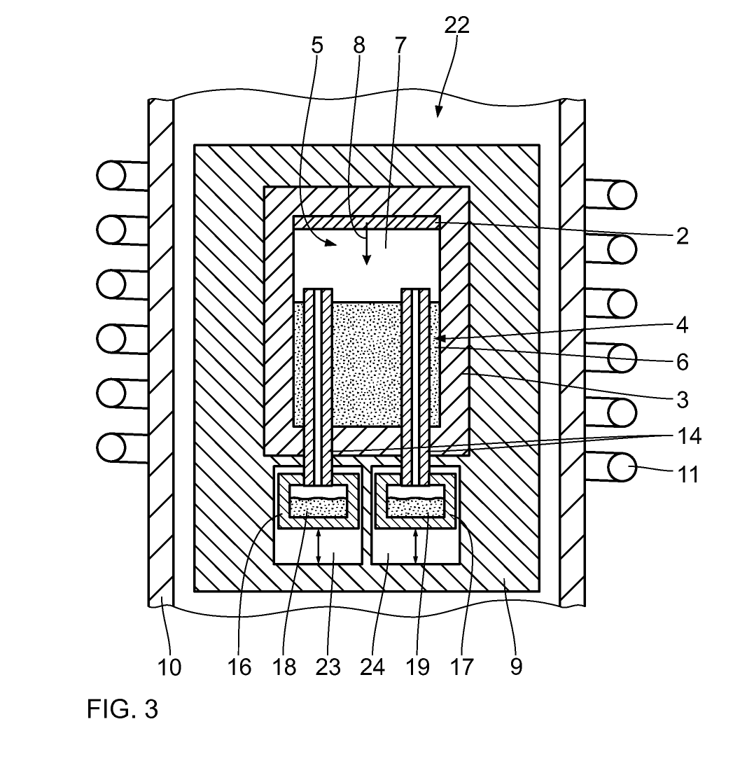

FIG. 3 is a diagrammatic, sectional view of a third exemplary embodiment of a growing arrangement for the production of a high-impedance bulk SiC crystal with two external dopant supplies whose positions can be varied;

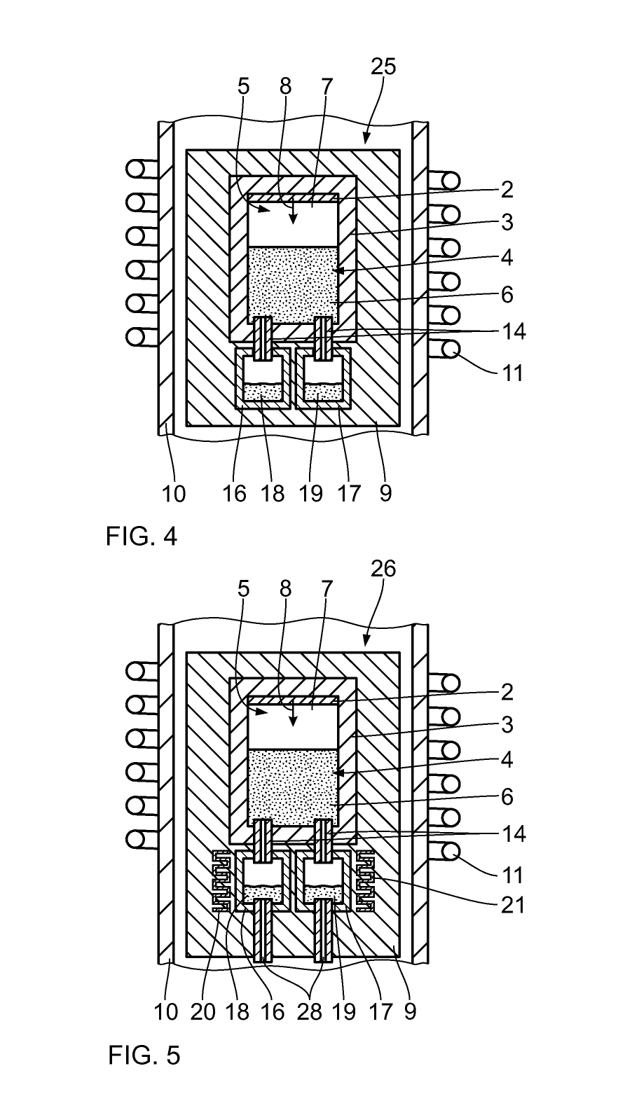

FIG. 4 is a diagrammatic, sectional view of a fourth exemplary embodiment of a growing arrangement for the production of a high-impedance bulk SiC crystal with two external dopant supplies and delivery of the dopants into the SiC source material;

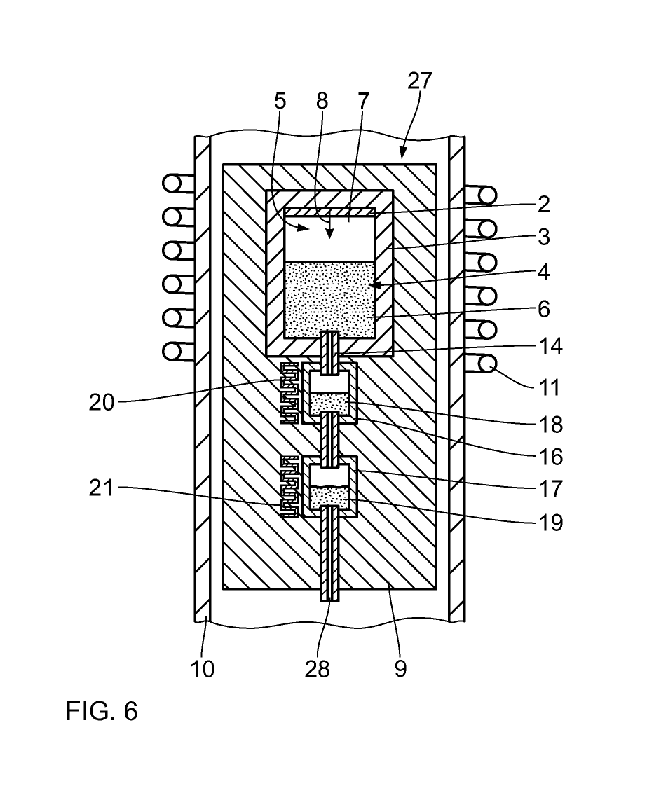

FIGS. 5 and 6 are diagrammatic, sectional views of a fifth and a sixth exemplary embodiment of a growing arrangement for the production of a high-impedance bulk SiC crystal with two dopant supplies through which an inert gas flows;

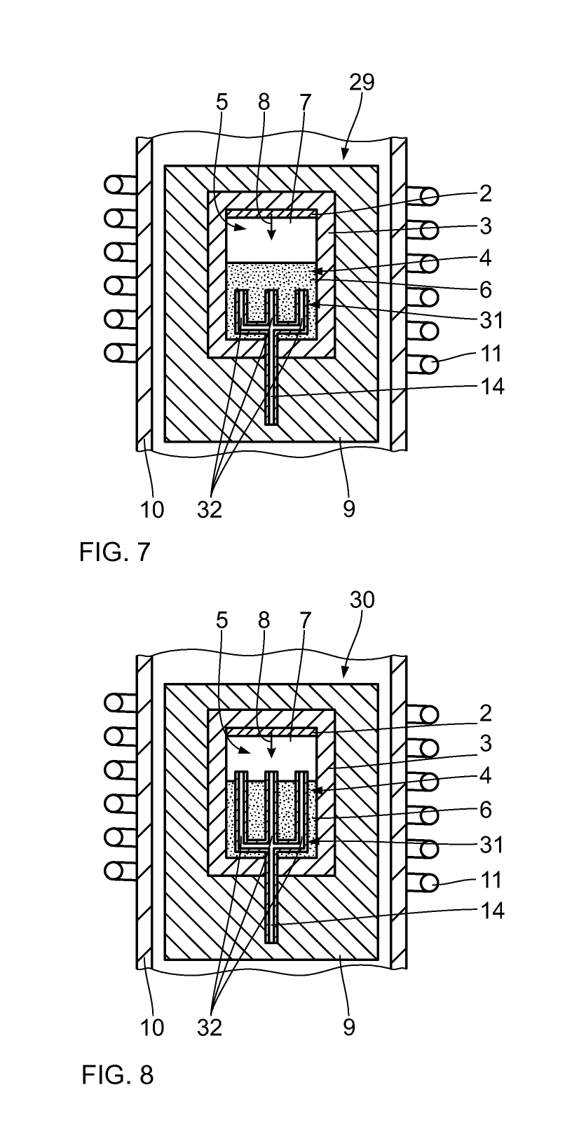

FIGS. 7 and 8 are diagrammatic, sectional views of a seventh and an eighth exemplary embodiment of a growing arrangement for the production of a high-impedance bulk SiC crystal with introduction of the dopants into the growing crucible by a gas distributor; and

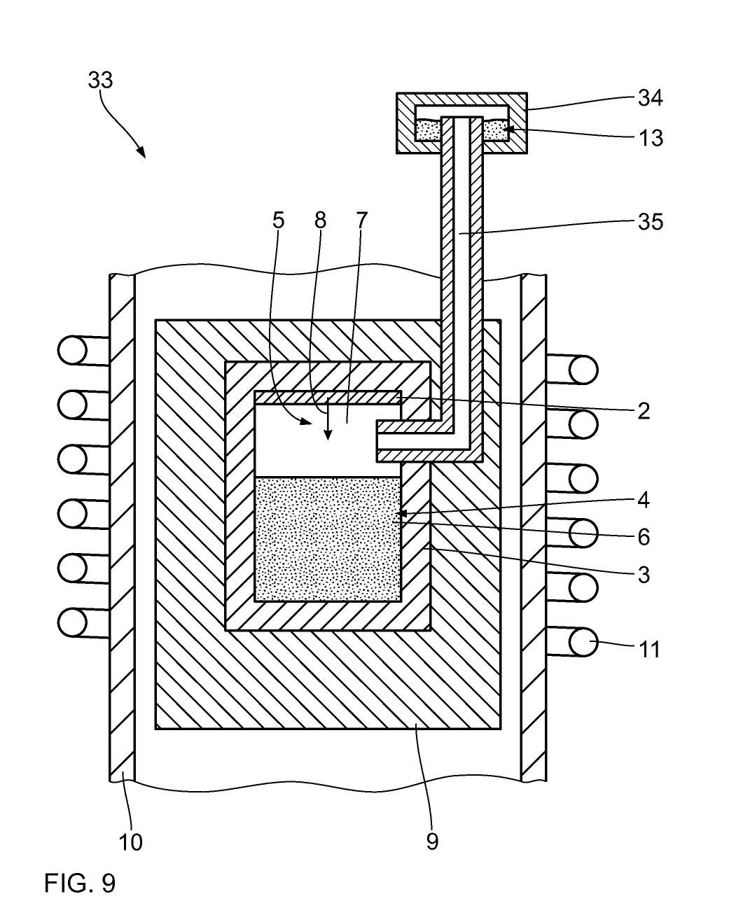

FIG. 9 is a diagrammatic, sectional view of a ninth exemplary embodiment of a growing arrangement for the production of a high-impedance bulk SiC crystal with a dopant supply arranged outside the thermal insulation of the growing crucible.

### DETAILED DESCRIPTION OF THE INVENTION

Parts which correspond to one another are provided with the same references in FIGS. 1 to 9.

Referring now to the figures of the drawing in detail and first, particularly, to FIG. 1 thereof, there is shown an exemplary embodiment of a growing arrangement 1 for the production of a high-impedance bulk SiC crystal 2. It contains a growing crucible 3 made of graphite, which contains an SiC supply region 4 and a crystal growth region 5. The SiC supply region 4 contains for example powdered SiC source material 6, with which the SiC supply region 4 of the growing crucible 3 is filled as a prefabricated starting material before the start of the growing process.

In the crystal growth region 5, a seed crystal (not represented in detail) is applied on an inner wall of the growing crucible 3 lying opposite the SiC supply region 4. The bulk SiC crystal 2 to be produced grows from the seed crystal by deposition from an SiC growth phase 7 which is formed in the crystal growth region 5.

The SiC growth phase 7 is obtained by sublimation of the SiC source material 6 and transport of the sublimed gaseous parts of the SiC source material 6 in the direction of a growth surface of the bulk SiC crystal 2. The SiC growth phase 7 contains at least gas constituents in the form of Si, Si₂C and SiC₂. The transport of the SiC source material 6 to the growth surface takes place along a temperature gradient. The temperature inside the growing crucible 3 decreases toward the growing bulk SiC crystal 2. The bulk SiC crystal 2 grows in a growth direction 8, which in the exemplary embodiment shown in FIG. 1 is oriented from the top downward, i.e. from the upper wall of the growing crucible 3 to the SiC supply region 4 arranged underneath.

A thermal insulation layer 9, for example of porous graphite, is arranged around the growing crucible 3. The thermally insulated growing crucible 3 is placed inside a tubular container 10, which in the exemplary embodiment is configured as a quartz glass tube and forms an autoclave. In order to heat the growing crucible 3, a heating coil 11 is arranged around the container 10. The relative positions of the heating coil 11 and the growing crucible 3 can be varied in the growth direction 8, particularly in order to adjust the temperature or the temperature profile inside the growing crucible 3, and if need be also change it. The growing crucible 3 is heated to temperatures of more than 2000° C. by the heating coil 11.

Outside the growing crucible 3, i.e. below it, a dopant supply 12 which contains a, for example, powdered dopant material 13 is arranged inside the thermal insulation layer 9. The dopant supply 12 is connected to the interior of the growing crucible 3 by an inlet tube 14. The inlet tube terminates with its opposite end from the dopant supply 12 above the SiC supply region 4, i.e. inside the crystal growth region 5. This is not mandatory. In another embodiment, which is represented for example in FIGS. 4 to 6, the inlet tube 14 also terminates inside the SiC supply region 4. The dopant supply 12 is formed as a separate crucible, which is arranged inside a cavity in the thermal insulation layer 9.

In the exemplary embodiment, the dopant material 13 contains either a single dopant, i.e. vanadium, or a dopant mixture consisting of a first and a second dopant, the first dopant being aluminum and the second dopant being vanadium. These dopants evaporate or sublime inside the dopant supply 12 and enter the interior of the growing crucible 3 in the gaseous state, so that they are incorporated into the growing bulk SiC crystal 2. If vanadium is provided as the only dopant, the dopant atoms will be incorporated as acceptors which have a low-lying dopant level at a distance of about 700 meV from the SiC band edge. If codoping with aluminum and vanadium respectively as the first and second dopants is provided, the aluminum atoms will be incorporated as flat acceptors with a dopant level at a distance of about 250 meV from the SiC band edge and the vanadium atoms will be incorporated as low-lying donors with a dopant level at a distance of about 1400 meV from the SiC band edge.

In both cases, a high-impedance bulk SiC crystal is obtained with a resistivity of at least 10¹¹ Ωcm with monodoping or at least 10¹² Ωcm with codoping. Owing to the external arrangement of the dopant supply 12, the incorporation of the dopants can be adjusted deliberately and above all variably so that a substantially homogeneous, high-impedance electrical behavior is achieved inside the growing bulk SiC crystal 2.

FIG. 2 represents an alternative exemplary embodiment of a growing arrangement 15. In contrast to the growing arrangement 1 according to FIG. 1, it contains two dopant supplies 16 and 17 which are external, i.e. arranged outside the growing crucible 3, aluminum as a first dopant material 18 being introduced into the dopant supply 16 and vanadium as a second dopant material 19 being introduced into the dopant supply 17. The two dopant supplies 16 and 17 are assigned their own separately drivable heater 20 and 21, respectively. The dopant supplies 16 and 17 can therefore have their temperature regulated or controlled individually, and in particular independently of the heating of the growing crucible 3 by the heating coil 11. Above all, it is possible to vary the heating of the dopant supplies 16 and 17 during the course of the growing process.

In the further exemplary embodiment of a growing arrangement 22 as shown in FIG. 3, variable adjustment of the temperature inside the dopant supplies 16 and 17 is achieved by the relative positions of the dopant supplies 16 and 17 respectively being variable in relation to the growing crucible 3 and the heating coil 11. To this end positioning devices (not represented in detail) may be provided, which make it possible to displace the dopant supplies 16 and 17 in the growth direction 8. The cavities 23 and 24 provided inside the thermal insulation layer 9 in order to hold the dopant supplies 16 and 17 are therefore larger in the axial direction, i.e. in the growth direction 8, than the axial dimension of the respective dopant supply 16 or 17.

Owing to the variable heating of the dopant supplies 16 and 17 and the consequent variably adjustable temperatures of the dopant materials 18 and 19, the delivery of the dopants aluminum and vanadium can very exactly be adjusted and adapted to modified process conditions. This ensures that the growing bulk SiC crystal 2 has substantially homogeneous electrical properties in the axial direction. In the growth direction 8, there is therefore essentially the same high resistivity value at every position, which takes a value of at least 10¹² Ωcm when codoping with aluminum and vanadium. All monocrystalline SiC substrates which are obtained from this bulk SiC crystal 2, by axially cutting or sawing them successively as wafers perpendicularly to the growth direction 8, then have virtually the same electrical properties in each case.

In the further exemplary embodiments of alternative growing arrangements 25, 26 and 27 according to FIGS. 4 to 6, the respective inlet tubes 14, by which the gaseous dopants from the dopant supplies 16 and 17 are introduced into the interior of the growing crucible 3, do not extend into the crystal growth region 5 but already terminate in the SiC supply region 4. The resulting passage of the gaseous dopants through the SiC source material 6 leads to an advantageous, substantially uniform distribution of the gaseous dopants within an inner cross-sectional area of the growing crucible 3 oriented perpendicularly to the growth direction 8.

Also when growing a very large bulk SiC crystal 2 which in particular has a diameter of at least 7.62 cm (at least 3 inches), the incorporation of the dopants preferably takes place substantially uniformly in the lateral (radial) direction, i.e. in an arbitrary direction perpendicular to the growth direction 8. The electrical behavior of the bulk SiC crystal 2 is therefore subject to virtually no variations in the lateral direction. In particular, the resistivity has virtually the same high resistivity everywhere in the lateral direction, i.e. at least 10¹² Ωcm in a codoping method with two dopants or at least 10¹¹ Ωcm in a monodoping method with only one dopant. In particular, the resistivity for an arbitrary 4 mm² large square sub-area of a SiC substrate produced in the form of a wafer from the bulk SiC crystal 2 is at least 10¹² Ωcm or at least 10¹¹ Ωcm, respectively, depending on the doping method used. A main substrate surface of such a SiC substrate is oriented perpendicularly to the growth direction 8. In the growth direction 8, such a SiC substrate has for example a substrate thickness of about 200 μm to 500 μm, in particular 350 μm.

In the growing arrangements 26 and 27, an inert gas additionally flows through the dopant supplies 16 and 17 which can again be heated deliberately by the heaters 20 and 21, this inert gas being introduced into the dopant supplies 16 and 17 from outside the insulation layer 9. From there, the inert gas together with the gaseous dopants enters the interior of the growing crucible 3 so as to provide improved transport of the gaseous dopants into the growing crucible 3 and an additional way of regulating the dopant quantity introduced. Furthermore, the inert gas flow substantially prevents the delivery line 14 from being constricted by growth of SiC. For the inert gas delivery, the dopant supplies 16 and 17 are provided with a delivery tube 28 extending outward.

The dopant supplies 16 and 17 may be arranged separately from one another, and in particular adjacent, as represented in FIGS. 2 to 5. According to the growing arrangement 27 shown in FIG. 6, however, the dopant supplies 16 and 17 may also be arranged one behind the other, i.e. in series with one another.

FIGS. 7 and 8 show further exemplary embodiments of other growing arrangements 29 and 30. For the sake of simplicity, the dopant supplies 12, and respectively 16 and 17, are not also represented. They are present in a similar way as in the exemplary embodiments according to FIGS. 1 to 6. The inlet tube 14, which is connected to these not explicitly represented dopant supplies 12, and respectively 16 and 17, opens inside the growing crucible into a gas distributor 31 which contains a plurality of outlet tubes 32. The outlet tubes 32 may again terminate either still inside the SiC supply region 4 (see FIG. 7) or not until inside the crystal growth region 5 (see FIG. 8). In each case, the outlet tubes 32 are arranged distributed within an inner cross-sectional area oriented perpendicularly to the growth direction 8, so that the gaseous dopants being delivered are distributed uniformly within this cross-sectional area.

A particularly homogeneous distribution of the dopants is therefore achieved in the lateral direction both inside the SiC growth gas phase 7 and in the bulk SiC crystal 2 growing from it. Thus, in a SiC substrate produced from the growing bulk SiC crystal 2, the local concentration of the incorporated dopant varies by less than 5% of an overall concentration of this dopant, determined for the entire SiC substrate, for an arbitrary sub-volume which contains the complete substrate thickness in the growth direction 8 and is 4 mm² large perpendicularly thereto. In the lateral direction, the concentration of the dopants thus varies by at most 5% around the relevant average concentration value—this being for a diameter of the SiC substrate or the bulk SiC crystal 2 of at least 7.62 cm (=at least 3 inches).

Owing to the measures described above, the bulk SiC crystal 2 can thus be produced with very good homogeneity of the respectively incorporated dopants in both the lateral and axial directions, even when the diameter of the growing bulk SiC crystal 2 is extraordinarily large.

FIG. 9 represents a further exemplary embodiment of a growing arrangement 33, in which a dopant supply 34 is arranged not only outside the growing crucible 3 but also outside the associated thermal insulation layer 9. In this embodiment as well, the temperature of the dopant material 13 arranged in the dopant supply 34 is adjusted separately. The gaseous dopants are again delivered into the interior of the growing crucible 3 by means of an inlet tube 35, and in the exemplary embodiment shown, directly into the crystal growth region 5.

The growing arrangements 1, 15, 22, 25 to 27, 29, 30 and 33 described above and the associated growing methods for producing the high-impedance bulk SiC crystal 2 may be used both for codoping with at least two dopants and for monodoping with only a single dopant. The advantages of the particularly homogeneous incorporation of the dopants, and the likewise particularly homogeneous high-impedance resistivity resulting from this, are equally well achieved in both doping methods.

1. A method for producing a bulk SiC crystal having a resistivity of at least 10¹² Ωcm and having a diameter of at least 7.62 cm, which comprises the steps of:
generating an SiC growth gas phase in a crystal growth region of a growing crucible, and the bulk SiC crystal grows by means of deposition from the SiC growth gas phase;
feeding the SiC growth gas phase from an SiC source material, which is contained in an SiC supply region inside the growing crucible; and
delivering first dopants having a flat dopant level at a distance of at most 350 meV from an SiC band edge, and second dopants having a low-lying dopant level at a distance of at least 500 meV from the SiC band edge, in gaseous form to the crystal growth region from at least one dopant supply disposed outside the growing crucible and a temperature of which can be controlled independently of the SiC source material.

2. The method according to claim 1, which further comprises heating the dopant supply separately from heating of the growing crucible.

3. The method according to claim 1, which further comprises disposing the dopant supply in a cavity which is provided inside a thermal insulation layer surrounding the growing crucible.

4. The method according to claim 1, which further comprises varying a position of the dopant supply relative to the growing crucible.

5. The method according to claim 1, which further comprises supplying an inert gas flow through the dopant supply.

6. The method according to claim 1, which further comprises delivering the first dopants and the second dopants from one of a common dopant supply and from separate dopant supplies.

7. The method according to claim 1, which further comprises introducing the first and second dopants one of into the SiC supply region and directly into the crystal growth region.

8. The method according to claim 1, which further comprises distributing the first and second dopants inside the growing crucible by introducing them into the growing crucible in relation to a cross-sectional plane of the growing crucible oriented perpendicularly to a growth direction.

9. The method according to claim 1, which further comprises delivering the first and second dopants to the crystal growth region so that their respective concentrations within a cross-sectional plane of the growing crucible oriented perpendicularly to a growth direction vary by at most 5% around an average concentration value.

10. The method according to claim 1, which further comprises distributing the first and second dopants inside the growing crucible by introducing them into the growing crucible in relation to a cross-sectional plane of the growing crucible oriented perpendicularly to a growth direction, and at a plurality of adjacent positions.

11. A monocrystalline SiC substrate, comprising:
a main substrate surface having a diameter of at least 7.62 cm;
a codoping with a first dopant and a second dopant, said first dopant having a flat dopant level that lies at a distance of at most 350 meV from an SiC band edge, and said second dopant having a low-lying dopant level that lies at a distance of at least 500 meV from the SiC band edge; and
a resistivity determined for an arbitrary 4 mm² large sub-area of said main substrate surface being at least 10¹² Ωcm.

12. The SiC substrate according to claim 11, wherein said first dopant is an acceptor and overcompensates for impurities acting as donors.

13. The SiC substrate according to claim 11, wherein said first dopant is selected from the group consisting of aluminum and boron.

14. The SiC substrate according to claim 11, wherein said first dopant is aluminum and has a concentration of between 1·10¹⁶ cm⁻³ and 5·10¹⁷ cm⁻³.

15. The SiC substrate according to claim 11, wherein said second dopant is a donor and at least equalizes any overcompensation by said first dopant in relation to impurities.

16. The SiC substrate according to claim 11, wherein said second dopant is selected from the group consisting of vanadium and scandium.

17. The SiC substrate according to claim 11, wherein said second dopant is vanadium and has a concentration of between 1·10¹⁶ cm⁻³ and 5·10¹⁷ cm⁻³.

18. The SiC substrate according to claim 11, wherein said second dopant has a higher concentration than said first dopant.

19. The SiC substrate according to claim 11, wherein a local concentration of said first dopant, determined for an arbitrary sub-volume, deviates by less than 5% of an overall concentration of said first dopant, said sub-volume being defined by an arbitrary 4 mm² large sub-area of said main substrate surface and perpendicularly thereto by a substrate thickness.

20. The SiC substrate according to claim 11, wherein a local concentration of said second dopant, determined for an arbitrary sub-volume, deviates by less than 5% of an overall concentration of said second dopant, said sub-volume being defined by an arbitrary 4 mm² large sub-area of said main substrate surface and perpendicularly thereto by a substrate thickness.
